(19) United States
(12) Patent Application Publication
(10) Pub. No.: US 2018/0328677 A1
(43) Pub. Date: Nov. 15, 2018

(54) HEAT-DISSIPATING PLATE FOR HIGH-POWER ELEMENT

(71) Applicant: THE GOODSYSTEM CORP., Ansan-si, Gyeonggi-do (KR)

(72) Inventors: Il-ho KIM, Yongin-si, Gyeonggi-do (KR); Meoung-whan CHO, Yongin-si, Gyeonggi-do (KR); Young-suk KIM, Suwon-si, Gyeonggi-do (KR)

(73) Assignee: THE GOODSYSTEM CORP., Ansan-si, Gyeonggi-do (KR)

(21) Appl. No.: 15/566,215

(22) PCT Filed: Sep. 6, 2016
(86) PCT No.: PCT/KR2016/009982

§ 371 Date: Oct. 13, 2017

(51) Int. Cl. F28F 21/02; H05K 7/20; F28F 21/08

(52) U.S. Cl. CPC F28F 21/02; F28F 21/089; F28F 21/085; H05K 7/2039

(57) ABSTRACT

A heat-dissipating plate comprises a core layer; and two cover layers formed by being laminated on the top and bottom face of the core layer, wherein, the core layer is composed of a composite material in which a carbon phase is composited in a Cu matrix, the cover layer is composed of a Mo—Cu alloy, and the thermal conductivity in the thickness direction of the heat-dissipating plate is at least 300 W/mK, and the thermal expansion coefficient of the heat-dissipating plate in a direction perpendicular to the thickness direction is at most 9×10-6/K.

### TECHNICAL FIELD

The present invention relates to a heat-dissipating plate, and more particularly, to a heat-dissipating plate which may be suitably used in packaging for a high-power semiconductor element using a compound semiconductor, wherein the heat-dissipating plate has the same or a similar heat expansion coefficient as a ceramic material, such as alumina, to enable a satisfactory joint to be established even when joined with the ceramic material, and at the same time, can attain a high thermal conductivity capable of quickly discharging to the outside, large quantities of heat generated from the high-power semiconductor element.

### BACKGROUND ART

Recently, high-power amplifying elements using GaN-type compound semiconductors are receiving attention as a core technology in the fields of information and communications, and national defense.

Such high-power electronic elements or optical elements generate large quantities of heat compared to general elements, and packaging techniques are needed which can efficiently discharge such large quantities of heat.

Currently, metal-based composite materials, such as W/Cu double-layered composite materials, two-phase composite materials of Cu and Mo, Cu/Mo/Cu triple-layered composite materials, and Cu/Cu—Mo alloy/Cu triple-layered materials, having comparatively satisfactory thermal conductivities and low thermal expansion coefficients are being used in high-power semiconductor elements utilizing GaN-type compound semiconductors.

However, since the thermal conductivity of such composite materials is at most about 250 W/mK, high conductivities of 300 W/mK or higher required by several-hundred Watt-level power transistors are unable to be achieved, and thus the composite materials are limited in that application in elements such as several-hundred Watt-level transistor is difficult.

Moreover, brazing processes for joining with ceramic materials such as alumina (Al₂O₃) are essential in processes for manufacturing semiconductor elements, and since such brazing joining processes take place at high temperatures of at least 800° C., warping or damage occurs during the brazing joining process due to the difference in thermal expansion coefficient between the metal composite substrate and the ceramic material. Thus, there is also a limitation wherein the occurrence of such warping and damage causes defects in the elements.

### DISCLOSURE

### Technical Problem

The present invention is for overcoming limitations of typical techniques described above, and an object of the present invention is to provide a heat-dissipating plate which not only has a low thermal expansion coefficient of at most 9×10⁻⁶/K in the plane direction of the plate such that warping or damage does not occur when the heat-dissipating plate is joined with a ceramic material (in particular, alumina), but also has a high thermal conductivity of at least 300 W/mK (more desirably, at least 350 W/mK) in the thickness direction of the plate, and thus may be suitably used in a high-power element, such as a several-hundred Watt-level power transistor.

### Technical Solution

In order to overcome such limitations, the present invention provides a heat-dissipating plate for a high-power element, the heat-dissipating plate including a core layer and two cover layers formed by being laminated on the top and bottom faces of the core layer, wherein the core layer is composed of a composite material in which a carbon phase is composited in a Cu matrix, the cover layer is composed of a Mo—Cu alloy, the thermal conductivity in the thickness direction of the heat-dissipating plate is at least 300 W/mK, and the thermal expansion coefficient of the heat-dissipating plate in a direction perpendicular to the thickness direction is at most 9×10⁶/K.

### Advantageous Effects

A heat-dissipating plate according to the present invention can achieve a low thermal expansion coefficient in the plane direction of the plate of 9×10⁻⁶/K or less, while also attaining a high thermal conductivity in the thickness direction of the plate of at least 300 W/mK, and in the case of a more exemplary embodiment, at least 350 W/mK, and thus may be appropriately used as a heat-dissipating plate in a high-power semiconductor element requiring joining with a ceramic material, such as alumina, having a low thermal expansion coefficient.

### DESCRIPTION OF DRAWINGS

FIG. 1 schematically illustrates the cross-sectional structure in the thickness direction of a heat-dissipating plate manufactured according to Example 1 of the present invention.

FIG. 2 schematically illustrates the cross-sectional structure in the thickness direction of a heat-dissipating plate manufactured according to Example 2 of the present invention.

FIG. 3 is a scanning electron micrograph of a graphite powder used in the present invention.

FIG. 4 is a scanning electron micrograph of a thickness direction cross section of a heat-dissipating plate manufactured according to Example 1 of the present invention.

FIG. 5 is an expanded image of a Cu-graphite composite phase in a heat-dissipating plate.

FIG. 6 is a transmission electron micrograph of an interface of a Cu-graphite composite phase in a heat-dissipating plate manufactured according to Example 1 of the present invention.

FIG. 7 is a scanning electron micrograph of a thickness direction cross section of a heat-dissipating plate manufactured according to Example 2 of the present invention.

FIG. 8 is a scanning electron micrograph of a cover layer cross section in the thickness direction of a heat-dissipating plate manufactured according to Example 2 of the present invention.

FIG. 9 is a transmission electron micrograph of an interface of a Cu-graphite composite phase in a heat-dissipating plate manufactured according to Example 2 of the present invention.

FIG. 10 is a transmission electron micrograph of an interface of a Cu-graphite composite phase in a heat-dissipating plate manufactured according to Example 3 of the present invention.

FIG. 11 shows results of measuring the change in thermal conductivity according to graphite powder content (vol %) and sintering temperature (° C.).

FIG. 12 shows results of measuring the change in thermal expansion coefficient according to graphite powder content (vol %) and sintering temperature (° C.)

### BEST MODE

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art

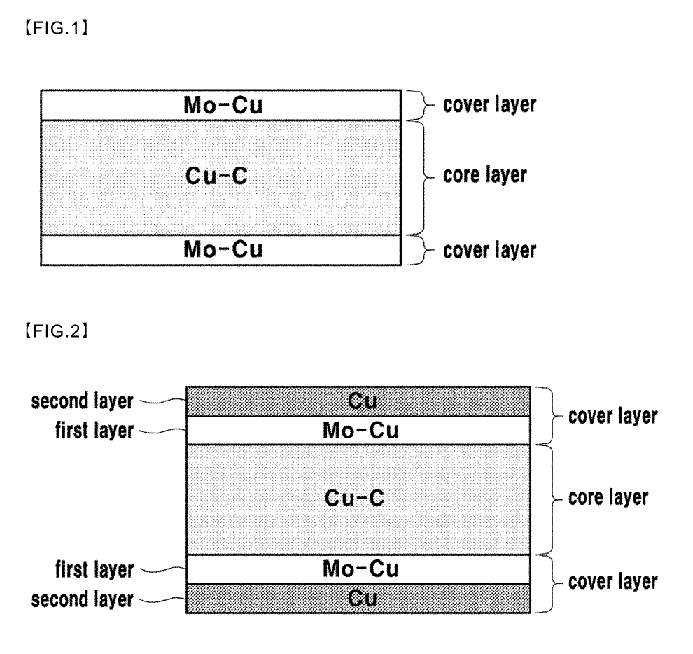

A heat-dissipating plate according to the present invention, as illustrated in FIG. 1, is characterized by including a core layer and two cover layers which are formed by being laminated on the top and bottom face of the core layer, wherein the core layer is composed of a composite material in which a carbon phase is composited in a Cu matrix, and the cover layer is composed of a Mo—Cu alloy. In the core layer, a graphite phase is oriented such that the long-length, longitudinal axis of the graphite phase is parallel to the thickness direction, a Cu—C diffusion region is formed to a thickness of 1-30 nm in at least a portion of the interface between the Cu matrix and the carbon phase, the thermal conductivity in the thickness direction of the heat-dissipating plate is at least 300 W/m, and the thermal expansion coefficient in a direction perpendicular to the thickness direction is 9×10⁻⁶/K.

In the present invention, the graphite phase being oriented parallel to the thickness direction indicates a state in which the graphite phase is oriented such that the average angle between a longitudinal axis direction, in which the length of graphite phase particles is long, is at most 45°, desirably, at most 30°, and more desirably, at most 20°, that is, the graphite particles are oriented such that the length direction is aligned in the thickness direction of the heat-dissipating plate.

Moreover, the thickness direction thermal conductivity of the heat-dissipating plate according to the present invention is more desirably at least 350 W/mK.

In addition, as illustrated in FIG. 2, the cover layer may be formed as a laminated structure of two or more layers, a first layer formed adjacent to the core layer may be composed of a Mo—Cu alloy, and a second layer not contacting the core layer may be composed of Cu.

Moreover, the Mo—Cu alloy may be an alloy that includes 10-55 wt % of Cu with respect to the total weight of the alloy.

Furthermore, the Cu may be pure Cu (including inevitable impurities) or a Cu alloy that includes at most 20 wt % of non-Cu alloying elements.

In addition, in the core layer, a Cu—C diffusion region formed by the diffusion of Cu and C is present in at least a portion of, or the entirety of, the interface of Cu and the carbon phase. When the width of this diffusion region is less than 1 nm, the thermal conductivity of the heat-dissipating plate is poor, and when the width of the diffusion region exceeds 30 nm, defects form in which voids collect and form in portions abandoned by diffusing atoms, and thus, thermal conductivity is poor. Therefore, it is desirable for the diffusion region to be formed to have a width of 1-30 nm in a direction perpendicular to the interface. For the perspective of thermal conductivity and thermal expansion coefficient, the width of the Cu—C diffusion region is more desirably 5-20 nm.

Moreover, the carbon phase may include graphite, diamond, graphene, or a diamond-like film, and the form of the carbon phase may be composed of completely plate-shaped particles, as well as irregularly-shaped particles having a particular face, such as scale-shaped or flake-shaped particles.

Furthermore, the carbon phase composited in the Cu matrix is desirably 45-70 vol % of the total volume of the composite phase. This is because, when the mixing amount of the carbon phase is less than 45 vol %, it is difficult for a low thermal expansion coefficient of 9×10⁻⁶/K or lower to be achieved over the entire heat-dissipating plate in the plane direction thereof, and when the mixing amount of the carbon phase exceeds 70 vol %, a limitation appears in which the adhesiveness with the cover layer when joined with the cover layer decreases. More desirably, the mixing amount of the carbon phase is 50-65 vol %.

In addition, the thickness of the core layer may desirably be 60-90% of the total thickness of the heat-dissipating plate. This is because, when the thickness of the core layer is less than 60% of the total thickness of the heat-dissipating plate, a low thermal conductivity of 300 W/mK or lower is exhibited, and when exceeding 90%, an excessively high thermal expansion coefficient of 9.5×10⁻⁶/K or higher is exhibited.

Moreover, when a cover layer formed on one side of the core layer is composed of a double-layered structure of Cu and a Mo—Cu alloy, the thickness of the layer composed of Cu is desirably 5-10% of the overall thickness of the heat-dissipating plate. This is because, when the thickness of the layer composed of Cu is less than 5% of the overall thickness of the heat-dissipating plate, thermal diffusion in the surface portion is low, and surface instability may arise when a chip such as GaN or GaAs is mounted on the surface portion, and when the thickness of the layer composed of Cu exceeds 10% of the overall thickness of the heat-dissipating plate, a large thermal expansion coefficient of 9.0×10⁻⁶/K is exhibited. In addition, the thickness of the layer composed of a Mo—Cu alloy and formed on one side of the core layer is also desirably 5-10% of the overall thickness of the heat-dissipating plate. This is because, when the thickness of the layer composed of a Mo—Cu alloy is less than 5% of the total thickness of the heat-dissipating plate, a high plane direction thermal expansion coefficient of 9.0×10⁻⁶/K is exhibited, and when exceeding 10%, a low thermal conductivity of 300 W/mK or lower is exhibited in the perpendicular direction.

Furthermore, as a method for forming the heat-dissipating plate, a method may be used, including (a) a step for forming a first layer using a plate composed of a Mo—Cu alloy, (b) a step for forming a second layer on the first layer, the second layer being formed using a plate composed of a perpendicularly oriented carbon phase and Cu, (c) a step for forming a third layer on the second layer, the third layer being formed using a Mo—Cu alloy plate, and (d) a step for joining laminated materials.

In addition, in order to form a heat-dissipating plate including a cover layer composed of a laminated structure of two or more layers, a method may be used, including (a) a step for forming a first layer using a Cu plate, (b) a step for forming a second layer using a Mo—Cu plate, (c) a step for forming a third layer using a plate composed of a perpendicularly oriented carbon phase and Cu, (d) a step for forming a fourth layer on the third layer, the fourth layer being formed using a Mo—Cu plate, (e) a step for forming a fifth layer using a Cu plate, and (f) a step for joining laminated materials.

Moreover, the efficiency of a process may be increased through a method in which, after unit plates composed of the first to third layers or the first to fifth layers are laminated into multiple layers, each unit plate is separated.

A method for separating the unit plates may be achieved through a process in which, after a lamination process is performed by repeatedly performing the above steps (a) to (c) multiple times, the above operation (d) is performed, and cutting is performed to include the first to third layers. Here, the cutting process may be achieved through equipment such as a wire saw, but is not limited thereto, and methods capable of cutting the plate manufactured according to the present invention may be used without limit.

Likewise, in the case of a heat-dissipating plate including a cover layer composed of a laminated structure of two or more layers, after steps (a) to (e), a unit plate may be separated through a cutting process.

Moreover, another method of separating a unit plate may involve laminating a carbon layer after steps (a) to (e), and then, after repeatedly performing steps (a) to (c) and sintering through step (d), separating a unit plate through an unsintered carbon layer.

Likewise, in the case of a heat-dissipating plate including a cover layer composed of a laminated structure of two or more layers, after steps (a) to (e), a carbon layer may be laminated, and then steps (a) to (e) may be repeatedly performed, sintering may be performed through step (f), and a unit plate may be separated through the unsintered carbon layer.

As such, a process using a carbon layer is capable of forming a plate without a cutting process that requires precision fabrication, and thus has the advantage of reducing the manufacturing time of a unit plate.

The carbon layer may, for example, be composed of a binder mixture composed of a graphite powder and an organic material for forming the graphite powder.

For the first layer and third layer in the heat-dissipating plate having a single cover, or the first layer, second layer, fourth layer, and fifth layer in the heat-dissipating plate including a cover layer composed of a laminated structure of two or more layers, a method for laminating the corresponding metal plate may also be used, and selectively, the metal plate may also be formed by a plating technique.

In the joining step, the joining temperature is desirably 800-1050° C. This is because, when the joining temperature is below 800° C., joining is insufficiently carried out, and thus a low thermal conductivity may be exhibited or a limitation may occur in which the bonding strength between the cover layer and the core layer is weakened, and when the joining temperature exceeds 1050° C., melting of Cu included in the core layer may occur during the joining process such that Cu and the carbon phase are separated or rapid contraction occurs during solidification, thereby forming defects, such as cracking and the like, and as a result, causing a rapid decrease in thermal conductivity. More desirably, the joining temperature is 910-970° C.

A Cu coating layer is desirably formed on the surface of the carbon phase powder used in forming the core layer, and the Cu coating layer may be formed using a method such as, for example, plating. As such, the Cu-coated carbon phase powder is not only desirable for forming an appropriate interface between the Cu matrix and the carbon phase in the composite phase after sintering, but also assists in maintaining the bonding strength between the core layer and cover layer, and thus performs the role of preventing the occurrence of peeling at the interface between the core layer and cover layer during the course of using the heat-dissipating plate.

### EXAMPLE 1

A plate-shaped first layer, in which 50-100 μm thick Mo—Cu (64 wt % Mo-36 wt % Cu) plates are stacked, was formed in a mold.

Also, in Example 1 of the present invention, a second layer composed of Cu and a graphene phase was formed using a plate shape obtained by sintering Cu-plated graphene powder.

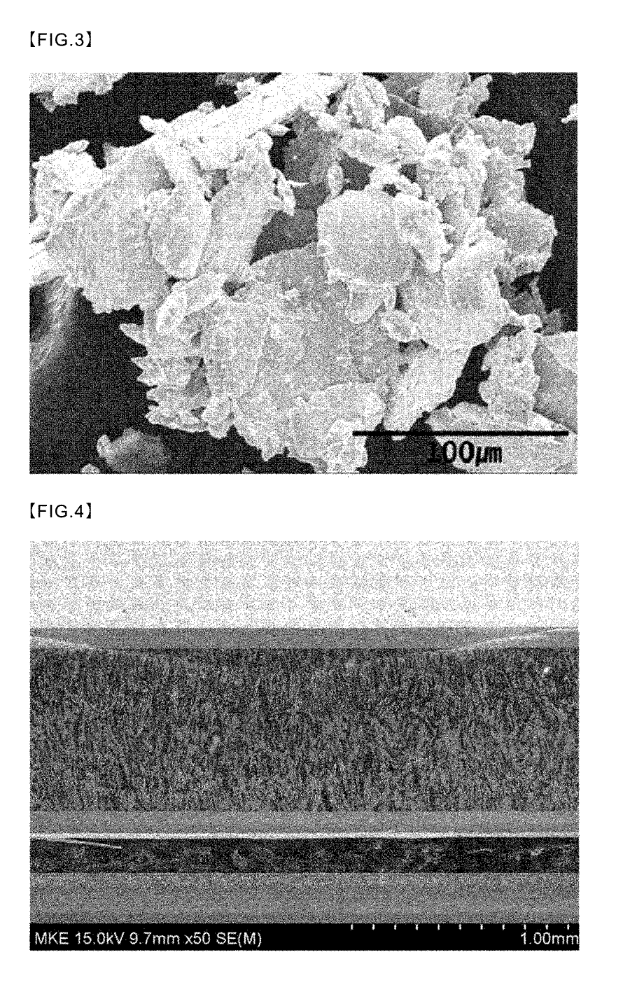

The graphene powder used was formed in a scale shape, such as illustrated in FIG. 3, and had an average particle size of about 130 μm. A Cu coating layer was formed on the surface of the graphene powder in order to ensure that when a core layer was formed through sintering, the interfacial bonding strength between the graphene powder and the Cu matrix and the bonding strength between a core layer and a cover layer positioned above and below the core layer was enhanced.

An electroless plating method was used in the formation of the Cu coating layer. Specifically, an activation treatment of the graphene powder is performed by heating the graphene powder for about 30-90 minutes at 300-400° C., and 3 wt % of glacial acetic acid is added with respect to the total weight of the graphene powder to facilitate the formation of Cu plating on the activation-treated graphene powder, after which a slurry is prepared by mixing 20 wt % of the mixture of the graphene powder and glacial acetic acid, 70 wt % of CuSO₄, and 10 wt % of water. After adding as a substitution solvent to the slurry thus obtained, Zn, Fe, or Al granulates having greater electronegativity than the metal of a Cu salt aqueous solution and having a size of about 0.7 mm, such that the content of the granulates is about 20 wt % with respect to the total weight of the slurry, stirring was performed at a rate of about 25 rpm at room temperature to form a Cu plating layer on the surface of the graphene powder. Moreover, passivation was carried out in order to prevent the Cu-coated graphene powder on which electroless plating was completed from corroding in the atmosphere, and for the passivation, the Cu-coated graphene powder is immersed for 20 minutes in a solution obtained by mixing distilled water, H₂SO₄, H₃PO₄, and tartaric acid in a weight ratio of 75:10:10:5. Finally, graphene powder in which the surface is coated with about 50 vol % of Cu was prepared by washing with water to remove residual acid on the graphene powder surface, and then heat-drying at 50-60° C. in atmosphere.

In this way, a 7-10 mm thick plate-shaped bulk material was manufactured by sintering the Cu-coated graphite powder at a pressure of 950° C. and a pressure of 50 MPa through a spark plasma sintering method. A bulk material having a thickness of 100 mm was manufactured by laminating ten layers of the manufactured plate shape. The manufactured bulk material was manufactured into a 1 mm thick plate shape by using a multi-wire saw to cut the bulk material to a thickness of 1 mm. In the case of this plate shape, scale-shaped graphite particles are in a state of being oriented parallel to the thickness direction of the plate shape, and the second layer was formed as this Cu graphite composite plate.

In addition, a plate-shaped third layer, in which 100-150 μm Mo—Cu (64 wt % Mo-36 wt % Cu) plates are stacked, was formed in a mold.

A plate in which the first to third layers are repeatedly laminated 10 or more times was obtained by repeating the process described above for laminating unit plates.

A final bulk material in which the first to third layers are joined into a multilayer is obtained by performing for 1-2 hours, pressurized joining in which the plate thus obtained is heated to 950° C. while applying a pressure of about 50 MPa thereto.

By using a diamond wire cutter to cut boundary portions of the unit plates in the bulk material thus obtained, a composite plate was obtained, in which a composite phase of Cu and graphite particles are formed in the middle (that is, the core layer) of the plate, and the cover layer of Mo—Cu is formed on the top and bottom faces of the core layer.

### EXAMPLE 2

A plate-shaped first layer, in which a 100-150 μm thick Cu plate is stacked, was formed in a mold.

Also, a plate-shaped second layer, in which a 50-100 μm thick Mo—Cu (64 wt % Mo-36 wt % Cu) is stacked, was formed on the first layer.

Also, in forming the third layer composed of Cu and a graphite phase, the third layer was formed by using a plate shape in which a Cu-plated graphite powder was manufactured by the same method as in Example 1 of the invention.

Also, a plate-shaped fourth layer, in which a 50-100 μm thick Mo—Cu (64 wt % Mo-36 wt % Cu) is stacked, was formed on the third layer.

Also, a plate-shaped fifth layer, in which a 100-150 μm thick Cu plate is stacked, was formed on the fourth layer.

In Example 2 of the present invention, Mo—Cu plates or Cu plates were used by being laminated, but the first layer, second layer, fourth layer, and fifth layer may also be formed by compression molding Mo—Cu or Cu powder.

By repeating the lamination process of unit plates as above, a plate-shaped heat-dissipating plate was obtained in which the first to fifth layers are repeatedly laminated at least 5 times.

A final bulk material in which the first to fifth layers are joined into a multilayer is obtained by performing for 1-2 hours, pressurized joining in which the plate thus obtained is heated to 950° C. while applying a pressure of about 50 MPa thereto.

By using a diamond wire cutter to cut boundary portions of the unit plates in the bulk material thus obtained, a composite plate was obtained, in which a composite phase of Cu and graphite particles are formed in the middle (that is, the core layer) of the plate, and a cover layer having a double-layered structure (Mo—Cu alloy/Cu) is formed on the top and bottom faces of the core layer.

### EXAMPLE 3

Processes other than the sintering process were performed identically to Example 2 of the present invention, and a metal-based composite plate was obtained by performing a sintering process of the core material at a sintering temperature of 900° C., an applied pressure of 80 MPa, and a sintering time of 20 minutes.

### EXAMPLE 4

Processes other than the sintering process were performed identically to Example 2 of the present invention, and a metal-based composite plate was obtained by performing a sintering process of the core material at a sintering temperature of 850° C., an applied pressure of 80 MPa, and a sintering time of 20 minutes.

FIG. 4 is a scanning electron micrograph of a thickness direction cross section of a heat-dissipating plate manufactured according to Example 1 of the present invention.

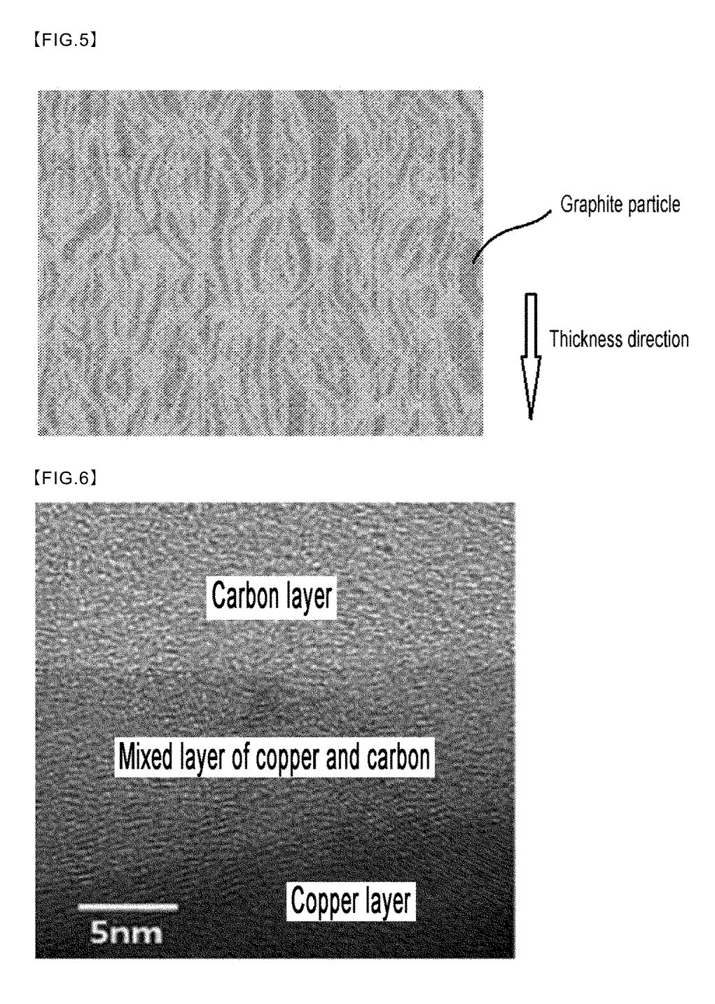

As illustrated in FIG. 4, a cover layer (the light grey part of the figure) absent a graphite particle phase and composed of a Mo—Cu alloy is formed to a depth of about 100 μm from the surface of the top face and bottom face of a heat-dissipating plate manufactured according to Example 1 of the present invention, and in the middle, a composite phase in which graphite particles are distributed in a Cu matrix is formed to a thickness of about 1 mm. Moreover, FIG. 5 is an image of a Cu-graphite composite phase, and it is confirmed that the length direction of the graphite particles is aligned parallel to the thickness direction of the plate.

FIG. 6 is a transmission electron micrograph of an interface of a Cu-graphite composite phase in a heat-dissipating plate manufactured according to Example 1 of the present invention.

As illustrated if FIG. 6, a region in which Cu and carbon have diffused is formed at an interface of Cu-graphite particles present in a composite phase, and it is confirmed that this diffusion region is formed, perpendicular to the interface, to a width of about 10 nm. Moreover, it was observed that in Example 2 also, a diffusion region is formed to a width of about 10 nm, which is the same as in Example 1.

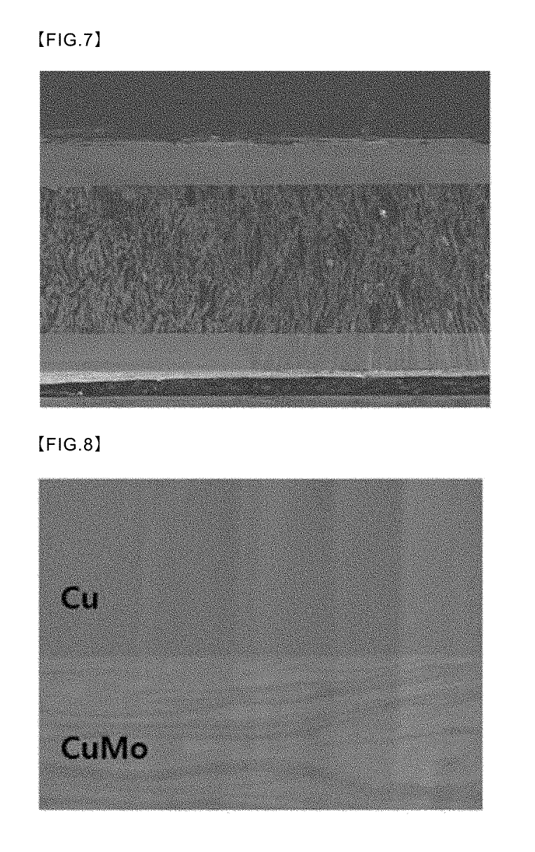

As illustrated in FIG. 7, a region absent a graphite particle phase and composed of Cu is formed from a depth of about 50 μm to about 100 μm from the surface of the top face and bottom face of a heat-dissipating plate manufactured according to Example 2 of the present invention, about a 50-100 μm thick region formed of Mo—Cu is formed below the region composed of Cu, and the middle is formed as a structure in which is formed a Cu—C composite layer.

FIG. 8 shows in greater detail, the structure of a cover layer in a heat-dissipating plate manufactured according to Example 2 of the present invention. As in the case of FIG. 7, the cover layer is formed as a Cu and Cu—Mo composite cover layer.

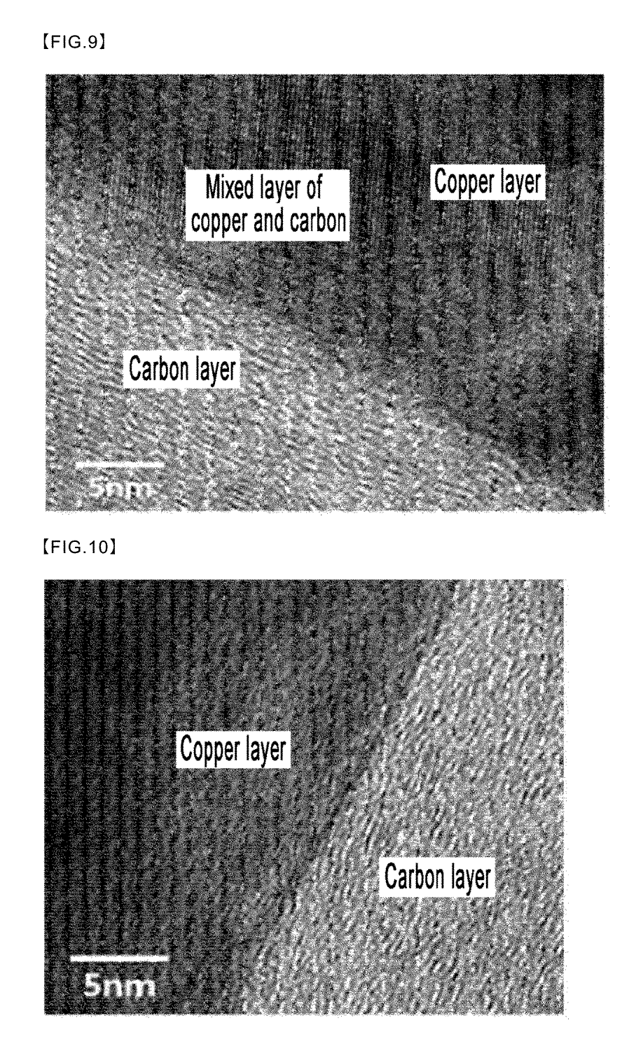

FIG. 9 is a transmission electron micrograph of an interface of a Cu-graphite composite phase in a heat-dissipating plate manufactured according to Example 2 of the present invention. As illustrated in FIG. 8, it can be seen that a region in which Cu and carbon are diffused is formed at the interface of Cu-graphite particles present in a composite phase.

FIG. 10 is a transmission electron micrograph of an interface of a Cu-graphite composite phase in a heat-dissipating plate manufactured according to Example 3 of the present invention.

As illustrated in FIG. 10, a region in which Cu and carbon have diffused to a width of at least 1 nm is not observed at the interface of Cu-graphite particles manufactured according to Example 3. Moreover, a region in which Cu and carbon have diffused to a width of at least 1 nm is also not observed at the interface of Cu-graphite particles in a heat-dissipating plate according to Example 4.

Table 1 below displays thickness direction thermal conductivities and thermal expansion ratios in the plane direction perpendicular to the thickness direction, of heat-dissipating plates manufactured according to Example 1-4 of the present invention.

TABLE 1

| | | | | Plane |
|---|---|---|---|---|
| | | Thickness | Thickness | direction |
| | | of Cu—C | direction | thermal |
| | Sintering | diffusion | thermal | expansion |
| | temperature | region | conductivity | coefficient |
| Item | (° C.) | (nm) | (W/mK) | (ppm/K) |
| Example 1 | 950 | about 10 | 397 | 7.6 |
| Example 2 | 950 | about 10 | 381 | 7.5 |
| Example 3 | 900 | not | 342 | 7.8 |
| | | observed | | |
| Example 4 | 850 | not | 338 | 8.2 |
| | | observed | | |

As shown in Table 1, Examples 1 and 2 of the present invention not only exhibit a thermal conductivity of 350 W/mK or higher, thus being capable of dissipating the large quantity of heat generated in a high-power electronic element, but can also maintain a low thermal expansion coefficient of 9×10⁻⁶/K or lower, and are thus able to prevent the occurrence of warping or damage in an essential process for joining with a ceramic material in a process for manufacturing a semiconductor element.

Meanwhile, in the case of Examples 3 and 4, a Cu—C diffusion phase is nearly unobservable in a Cu-graphite particle composite phase, and as a result, the thermal conductivity is on the level of about 340 W/mK, which is lower than in Examples 1 and 2, while the thermal expansion coefficient is maintained at or below 9×10⁻⁶/K, and thus appropriate heat dissipation is exhibited, while at the same time, a low thermal expansion coefficient required for joining with a ceramic material is satisfied. That is, Examples 3 and 4 may be appropriately used for joining with a ceramic material in cases requiring less heat dissipation than Examples 1 and 2.

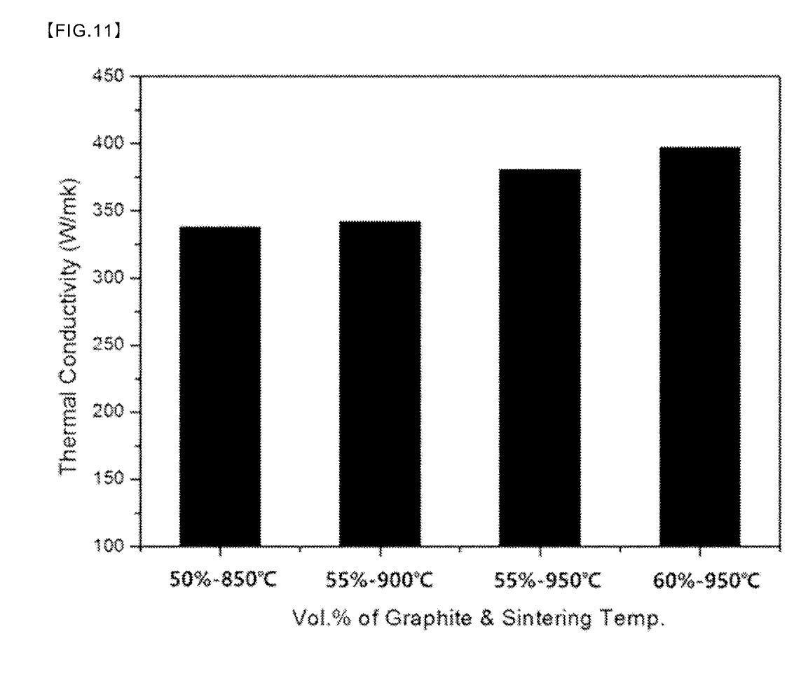

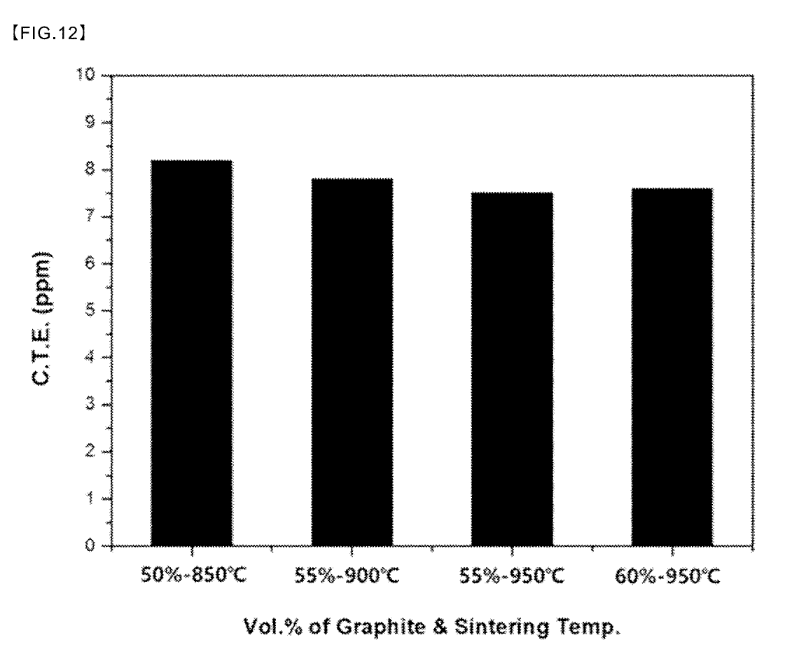

FIGS. 11 and 12 show in graph form, the change in thermal conductivity and thermal expansion coefficient according to graphite powder content and sintering temperature.

As confirmed in FIGS. 10 and 11, it can be seen that, in order to satisfy the high thermal conductivity and low thermal expansion coefficient required in several-hundred Watt-level power transistors, a graphite content of at least 50 vol % is desirable, and a sintering temperature exceeding 900° C. is more desirable.

Moreover, since a heat-dissipating plate according to Examples 1 to 4 of the present invention uses a Cu-graphite particle composite phase in which the graphite particles are coated with Cu, and thus the interfacial bonding strength between the graphite particles and a Cu base material is high and the bonding strength between a core layer and a cover layer composed of metal may be maintained high, a phenomenon may be prevented in which, during use, the core layer is separated from the cover layer present above and below the core layer.

1. A heat-dissipating plate for a high-power element, the heat-dissipating plate comprising:
a core layer; and
two cover layers formed by being laminated on the top and bottom face of the core layer, wherein,
the core layer is composed of a composite material in which a carbon phase is composited in a Cu matrix,
the cover layer is composed of a Mo—Cu alloy,
and the thermal conductivity in the thickness direction of the heat-dissipating plate is at least 300 W/mK, and
the thermal expansion coefficient of the heat-dissipating plate in a direction perpendicular to the thickness direction is at most 9×10-6/K.

2. The heat-dissipating plate according to claim 1,
wherein, the cover material is formed as a laminated structure of two or more layers;
a first layer formed adjacent to the cover layer is composed of a Mo—Cu alloy; and
a second layer, which does not contact the core layer and is formed on the first layer, is composed of Cu.

3. The heat-dissipating plate according to claim 1,
wherein, in the core layer, a Cu—C diffusion region is formed to a thickness of 1-30 nm in at least a portion of the interface between the Cu matrix and the carbon phase and the thermal conductivity in the thickness direction of the heat-dissipating plate is at least 350 W/mK.

4. The heat-dissipating plate according to claim 2,
wherein the Cu in the second layer is composed of pure Cu metal or is composed of a Cu alloy including at most 20 wt % of non-Cu alloying elements.

5. The heat-dissipating plate according to claim 1,
wherein, in the core layer, a Cu—C diffusion region is formed to a thickness of 5-20 nm in at least a portion of the interface between the Cu matrix and the carbon phase.

6. The heat-dissipating plate according to claim 1,
Wherein the carbon phase includes graphite, diamond, graphene, or a diamond-like film.

7. The heat-dissipating plate according to claim 1,
wherein the thickness of the core layer is 60-90% of the total thickness of the heat-dissipating plate.

8. The heat-dissipating plate according to claim 2,
wherein the thickness of the first layer is at most 5-10% of the total thickness of the heat-dissipating plate.

9. The heat-dissipating plate according to claim 1,
wherein, in the composite material in which the carbon phase is composited in the Cu matrix, the proportion of the carbon phase is 40-70% of the total volume of the composite material.

10. The heat-dissipating plate according to claim 1,
wherein the carbon phase composited in the Cu matrix is oriented such that the length direction of the carbon phase is parallel to the thickness direction of the heat-dissipating plate.

11. The heat-dissipating plate according to claim 2,
wherein, in the core layer, a Cu—C diffusion region is formed to a thickness of 1-30 nm in at least a portion of the interface between the Cu matrix and the carbon phase and the thermal conductivity in the thickness direction of the heat-dissipating plate is at least 350 W/mK.

12. The heat-dissipating plate according to claim 2,
wherein, in the core layer, a Cu—C diffusion region is formed to a thickness of 5-20 nm in at least a portion of the interface between the Cu matrix and the carbon phase.

13. The heat-dissipating plate according to claim 2,
Wherein the carbon phase includes graphite, diamond, graphene, or a diamond-like film.

14. The heat-dissipating plate according to claim 2,
wherein the thickness of the core layer is 60-90% of the total thickness of the heat-dissipating plate.

15. The heat-dissipating plate according to claim 2,
wherein, in the composite material in which the carbon phase is composited in the Cu matrix, the proportion of the carbon phase is 40-70% of the total volume of the composite material.

16. The heat-dissipating plate according to claim 2,
wherein the carbon phase composited in the Cu matrix is oriented such that the length direction of the carbon phase is parallel to the thickness direction of the heat-dissipating plate.
